(19) United States
(12) Patent Application Publication
(10) Pub. No.: US 2019/0146046 A1
(43) Pub. Date: May 16, 2019

(54) BRACKET WITH VERTICAL AND HORIZONTAL ADJUSTABILITY

(71) Applicant: KONINKLIJKE PHILIPS N.V., EINDHOVEN (NL)

(72) Inventors: JAMES HOWARD KRALICK, COLONIE, NY (US); MARTIJN KRELIS TERMEER, POPPEL (BE)

(21) Appl. No.: 16/308,920

(22) PCT Filed: Jun. 26, 2017
(86) PCT No.: PCT/EP2017/065669

§ 371 Date: Dec. 11, 2018

Related U.S. Application Data
(60) Provisional application No. 62/354,182, filed on Jun. 24, 2016.

(51) Int. Cl. G01R 33/38

(52) U.S. Cl. CPC G01R 33/3802; F16B 5/0225

(57) ABSTRACT

A superconducting magnet (10) has magnet mountings (22), each including a locking surface (60, 60a). A seismic mounting bracket (30) is secured to each magnet mounting by one or more bolts (46) passing through vertical through-slots (42) of the seismic mounting bracket and through-holes (44) of the magnet mounting. Each seismic mounting bracket has a locking surface (50, 50a) that is locked with the locking surface of the magnet mounting by mating surface features, e.g. horizontal teeth, of the respective locking surfaces. The surface features of each locking surface are periodic with a pitch P in the vertical direction to allow for a vertical positioning range. The bracket further has a horizontal mounting plate (32) with a through-hole (34) receiving a threaded rod floor anchor (20). An eccentric bushing assembly (70) including nested inner and outer eccentrics (72, 74) to allow for horizontal positioning tolerance is disposed in the through-hole (34).

### FIELD

The following relates generally to the seismic mounting arts, magnetic resonance (MR) imaging device arts, and the like.

### BACKGROUND

Mounting a magnet of a magnetic resonance (MR) imaging device is challenging. The magnet is a heavy component that requires vibrational and electrical isolation. The magnet should also be mounted level to a tight tolerance.

A known approach for providing vertical adjustment is to employ a bracket with a vertical slot. The mounted component (e.g. the MR magnet) has a bolt hole, and a bolt passes through the vertical slot and is secured at its distal end by a nut. In this design, vertical adjustment over a distance equal to the height of the slot length is achievable. The resistance to vertical movement under a seismic force is provided by preload of the tightened fastener, which in turn is determined by its tightening torque and the coefficient of friction (COF). For a bracket with N such bolt/nut fasteners, the vertical resisting force is therefore given by the product of the number of bolts (N), the preload (P) of each bolt, and the COF, i.e.:

F=N×P×COF

In practice, this vertical resisting force may not meet the minimum vertical resisting force required by governmental and/or other applicable regulations.

A higher vertical resisting force can be achieved by using more bolts, but this requires a larger bracket. Higher vertical resisting force can also be achieved by using a structural adhesive, but this complicates subsequent vertical bracket position adjustments that may be needed due to settling of vibration dampers or other reasons.

In the case of an MR magnet mounting bracket, the aforementioned structural characteristics, including seismic compliance, should be achieved while maintaining vibrational and electrical isolation of the magnet. Moreover, a design-basis horizontal and vertical positioning tolerance should also be met by the mounting bracket.

The following discloses a new and improved systems and methods that address the above referenced issues, and others.

### SUMMARY

In one disclosed aspect, a seismic mounting bracket assembly includes a bracket configured to be secured to a floor anchor. The bracket includes one or more through-slots oriented in a vertical direction when the bracket is secured to the floor anchor. The bracket further includes a flat bracket-side locking surface having surface features that are periodic with a pitch P in the vertical direction. A flat component-side locking surface is configured to lock to the flat bracket-side locking surface with one or more through-holes of the flat component-side locking surface aligned with the one or more through-slots of the bracket. The flat component-side locking surface has surface features that are periodic with the pitch P oriented in the vertical direction when the flat component-side locking surface is locked with the flat bracket-side locking surface.

In another disclosed aspect, a superconducting magnet assembly is disclosed. A superconducting magnet has a plurality of magnet mountings. Each magnet mounting includes a locking surface. A seismic mounting bracket is secured to each magnet mounting by one or more bolts passing through vertical through-slots of the seismic mounting bracket and through-holes of the magnet mounting. Each seismic mounting bracket has a locking surface that is locked with the locking surface of the magnet mounting by mating surface features of the respective locking surfaces of the magnet mounting and the seismic mounting bracket. The surface features of each respective locking surface of the magnet mounting and the seismic mounting bracket is periodic with a pitch P in the vertical direction.

In another disclosed aspect, a seismic mounting bracket assembly includes a bracket having a vertical plate with one or more vertical through-slots, and a horizontal plate with a through-hole sized to receive a threaded rod floor anchor. Nested outer and inner eccentric bushings are disposed in the through-hole of the horizontal plate.

One advantage resides in providing a seismic bracket having adjustable vertical position and improved resisting force against vertical seismic forces.

Another advantage resides in providing a seismic bracket having adjustable vertical position and improved resisting force against vertical seismic forces without the use of adhesive between the bracket and the component mounting.

Another advantage resides in providing a seismic bracket with large horizontal locational tolerance between the bracket and the floor anchor.

Another advantage resides in providing one or more of the foregoing advantages while maintaining vibrational isolation of the mounted component.

Another advantage resides in providing one or more of the foregoing advantages while maintaining electrical isolation of the mounted component.

Another advantage resides in providing a seismic bracket for mounting the superconducting magnet of a magnetic resonance (MR) imaging device in which the seismic bracket has one or more of the foregoing advantages.

Another advantage resides in facilitating an open bracket design to allow access for tooling.

A given embodiment may provide none, one, two, more, or all of the foregoing advantages, and/or may provide other advantages as will become apparent to one of ordinary skill in the art upon reading and understanding the present disclosure.

### BRIEF DESCRIPTION OF THE DRAWINGS

The invention may take form in various components and arrangements of components, and in various steps and arrangements of steps. The drawings are only for purposes of illustrating the preferred embodiments and are not to be construed as limiting the invention. Unless otherwise noted, the drawings are diagrammatic and are not to be construed as being to scale or to illustrate relative dimensions of different components.

FIG. 1 diagrammatically shows a perspective view of a superconducting magnet 10 of a magnetic resonance (MR) imaging device secured to a structural floor.

FIG. 2 diagrammatically shows a side view of the lower portion of the magnet of FIG. 1 and of the supporting floor.

FIG. 3 diagrammatically shows a perspective view of Detail D indicated in FIG. 1 including one of the seismic mounting brackets.

FIG. 4 diagrammatically shows a perspective view of one of the seismic mounting brackets of FIGS. 1-3 in isolation.

FIG. 5 diagrammatically shows a side sectional view of one of the seismic mounting brackets of FIGS. 1-3 in isolation. Detail B is also shown in enlarged view.

FIG. 6 diagrammatically shows the side sectional view of one of the seismic mounting brackets of FIG. 5 with the bracket-side locking plate moved away to reveal the receiving recess, and also showing the magnet mounting with the magnet-side locking plate secured to the magnet mounting.

FIGS. 7 and 8 diagrammatically show front views of an alternative embodiment of the mating locking plates including bracket-side locking plate (FIG. 7) and magnet mounting-side locking plate (FIG. 8).

FIG. 9 diagrammatically shows the horizontal mounting plate of the bracket of FIGS. 4-6 with an exploded view of the eccentric bushing assembly including nested outer and inner eccentric bushings, with the exploded view further revealing the anchor-mount through-hole sized to receive the floor anchor comprising a threaded rod.

### DETAILED DESCRIPTION

With reference to FIG. 1, a superconducting magnet 10 of a magnetic resonance (MR) imaging device is shown in diagrammatic perspective view. The magnet 10 includes a cryostat, such as a vacuum-jacketed liquid helium dewar, containing superconducting windings or coils. In FIG. 1, only the magnet cryostat is visible since the windings are internal components. The cryostat includes various ports 12 for adding liquid helium, making external contact to the superconducting windings to ramp current up or down, and so forth. The illustrative magnet 10 is a horizontal bore cylindrical magnet in which the windings encircle a central bore 14 within which a patient or other imaging subject is loaded for imaging. The skilled artisan recognizes the MR imaging device includes numerous additional components not illustrated in FIG. 1, such as magnetic field gradient coils typically having a cylindrical form-factor and disposed coaxially inside the central bore 14, radio frequency (RF) coils such as (for example) a whole-body birdcage or other whole-body coil having a cylindrical form-factor and disposed coaxially inside the central bore 14 (and usually inside the gradient coils) and/or one or more local coils or coil arrays, e.g. disposed on or near a portion of the imaging subject to be imaged. The MR imaging device also includes various electronics such as power supplies, gradient coil amplifiers, RF amplifiers, RF receiver electronics, and so forth, as well as an optional cosmetic housing or enclosure that may be disposed around the magnet 10; these features are again not illustrated in diagrammatic FIG. 1. In general, the MR imaging device of FIG. 1 may be any cylindrical bore superconducting-magnet MR imaging device, such as the Philips Ingenia 3.0T or 1.5T MR system. It is also to be appreciated that the cylindrical-bore magnet 10 of FIG. 1 is merely an illustrative mounted component, and the disclosed seismic mounting brackets may be used for mounting other types of MR magnets (e.g. vertical bore magnets, open magnets, or so forth) or for mounting large magnets for other types of devices or more generally any heavy component whose mounting should be seismically resistant and may optionally also preferably provide vibrational and/or electrical isolation (e.g. industrial robots for automotive assembly lines or the like; assembly line conveyor belts; and so forth).

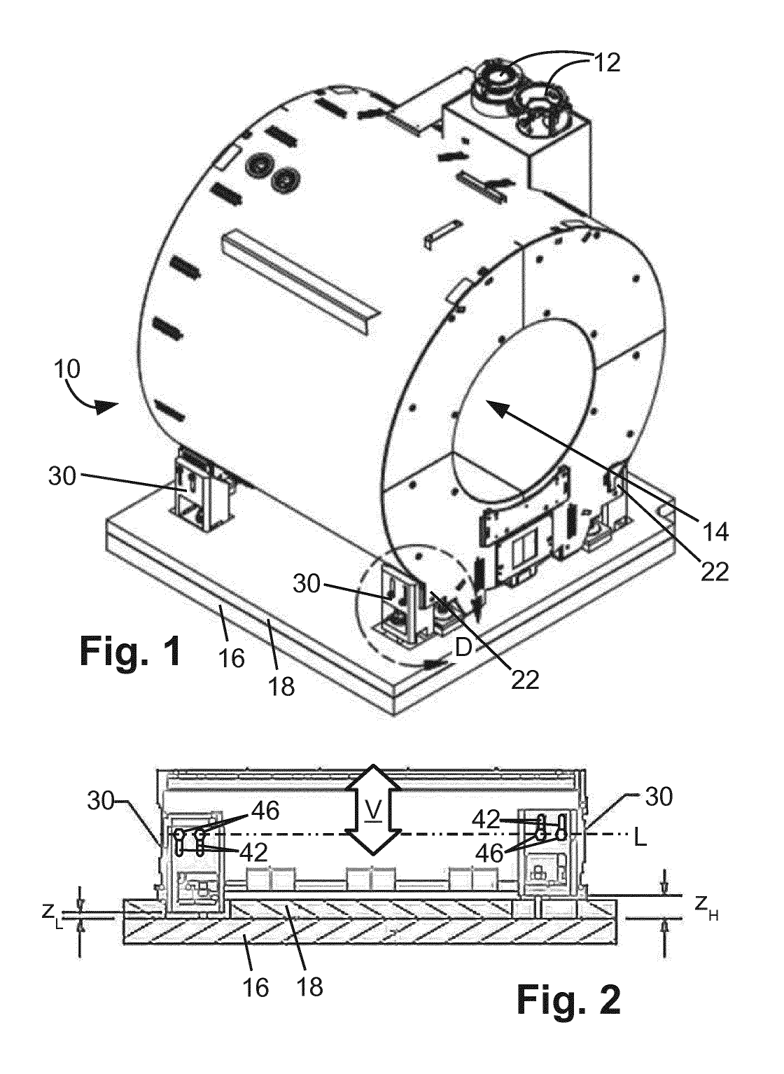

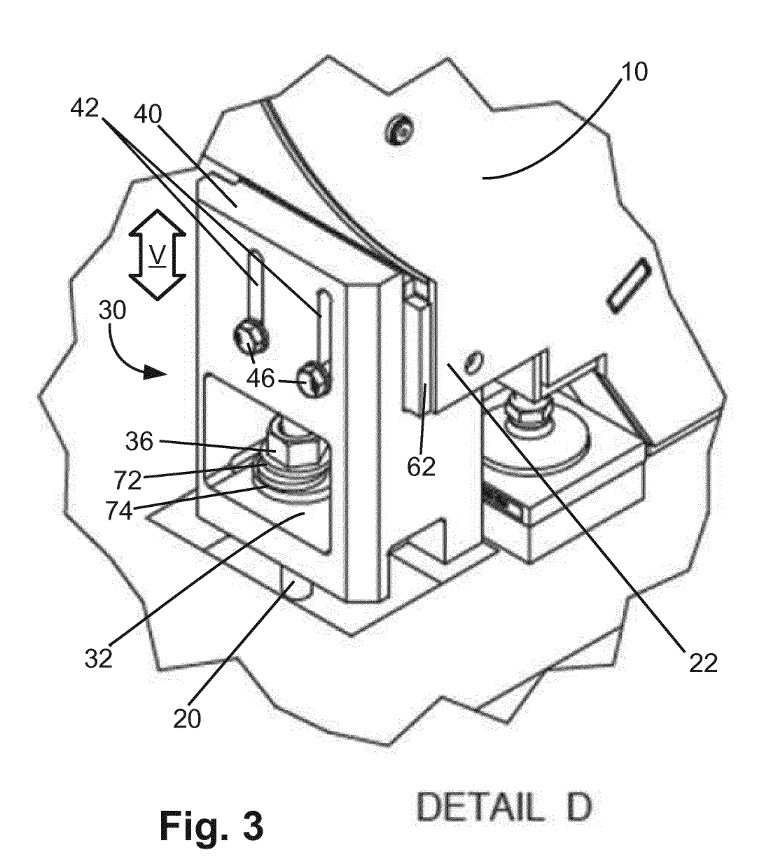

With continuing reference to FIG. 1 and with further reference to FIGS. 2 and 3, the magnet 10 is disposed on, and supported by, a structural floor such as an illustrative concrete floor 16. Optionally, a finished floor 18 may be disposed on top of the concrete floor 16; however, the weight of the magnet 10 calls for it to be supported by the structural floor 16 which is designed to support its weight. FIG. 2 diagrammatically shows a side view of the lower portion of the magnet 10 and of the supporting structural floor 16 and optional finished floor 18. As best seen in the “Detail D” view of FIG. 3 (showing the “Detail D” indicated in FIG. 1), floor anchors 20 are secured into the structural floor 16 and extend upward to provide anchor points for the magnet 10. The illustrative floor anchors 20 are threaded rods having their lower ends embedded into the structural floor 16 and extending vertically upward through the (optional) finished floor 18 to be accessible as floor anchors for mounting the magnet 10.

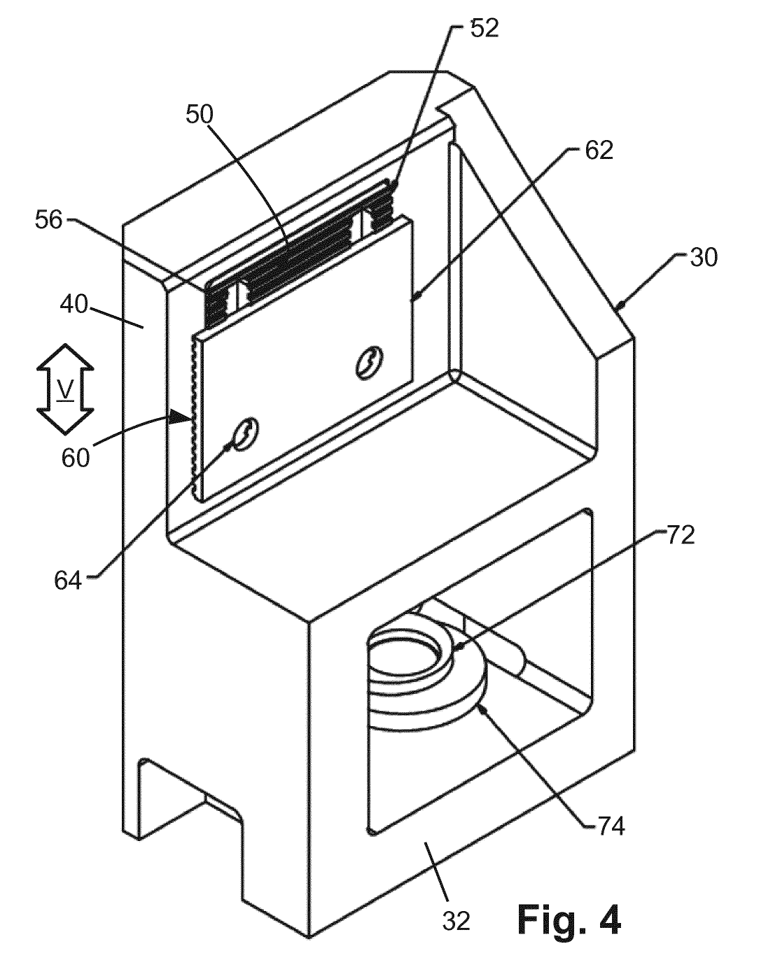

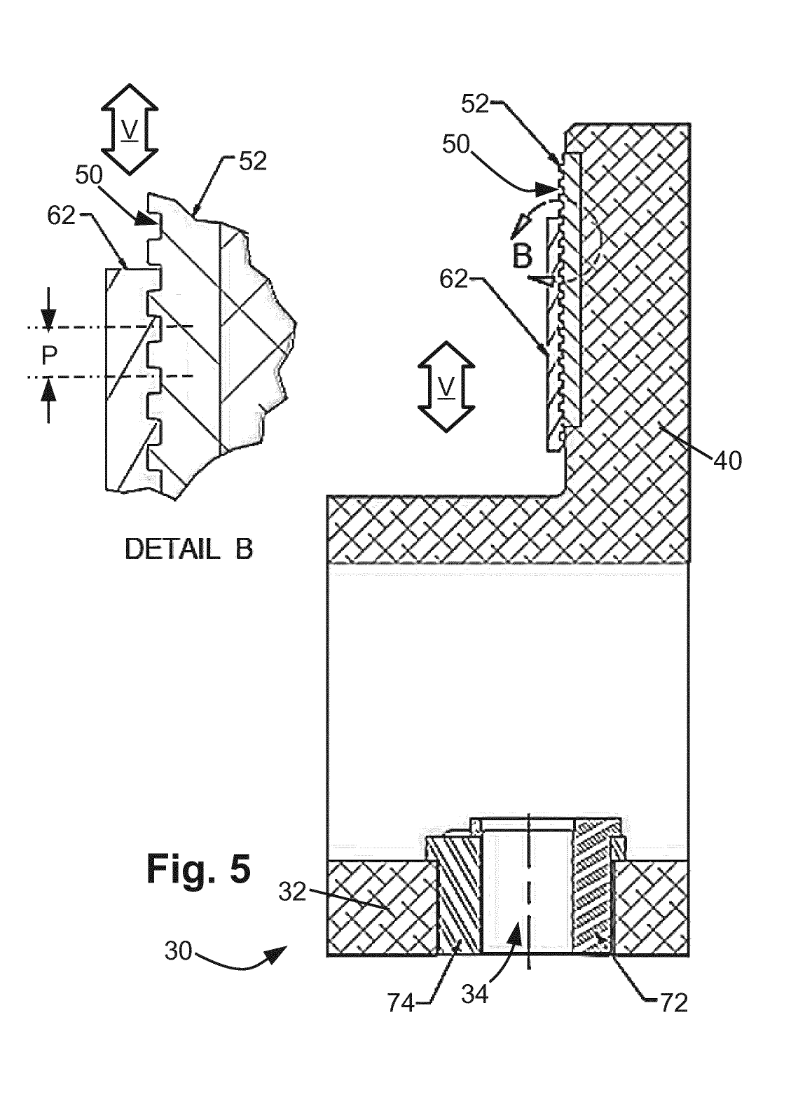

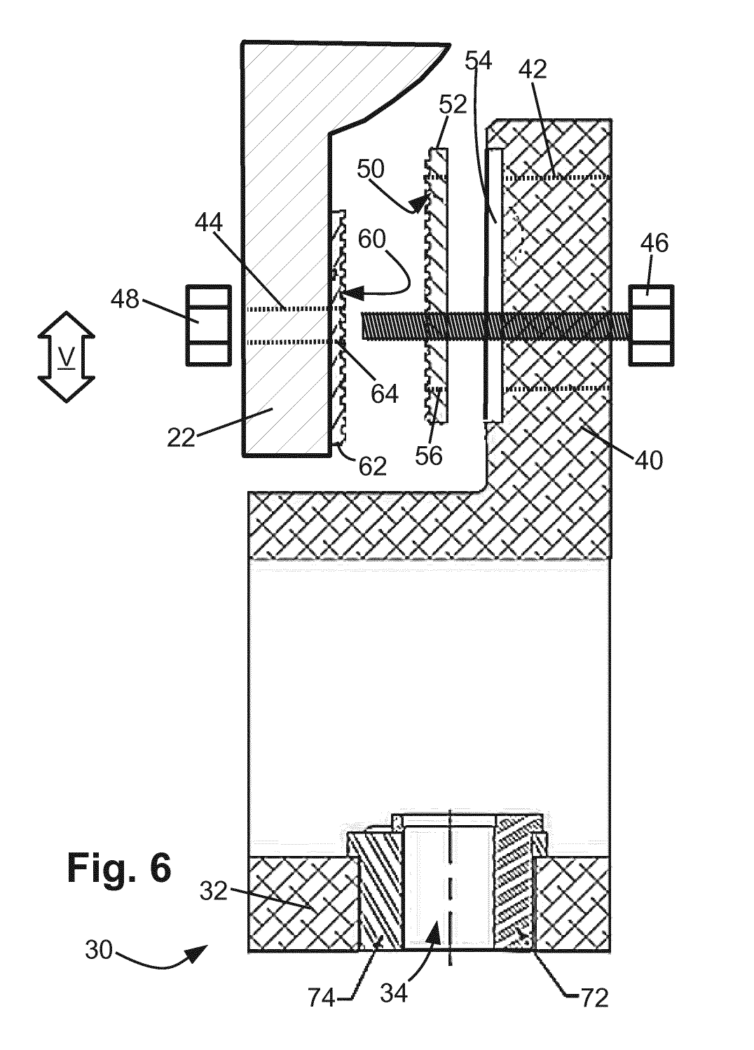

With continuing reference to FIGS. 1-3 and with further reference to FIGS. 4-6, the magnet 10 further includes magnet mountings 22 providing attachment points for connecting seismic mounting brackets 30 that secure the magnet 10 to the floor anchors 20. The “Detail D” view of FIG. 3 shows a perspective view of one seismic bracket 30 positioned in situ supporting the magnet 10. FIG. 4 diagrammatically shows a perspective view of the seismic mounting bracket 30 in isolation. FIG. 5 diagrammatically shows a side sectional view of the seismic mounting bracket 30 in isolation. In FIG. 5, the indicated “Detail B” is also shown in enlarged view in the upper left of FIG. 5. FIG. 6 diagrammatically shows the side sectional view of the seismic mounting bracket 30 as in FIG. 5, in partly exploded view also showing the magnet mounting 22. The bracket 30 is configured to be secured to the floor anchor 20. In the illustrative embodiment, this is by way of the bracket 30 including a horizontal mounting plate 32 which has an anchor-mount through-hole 34 that is sized to receive the floor anchor 20 (i.e. the threaded rod 20 in the illustrative case). The sizing may provide some extra gap to accommodate vibrations if vibration isolation is desired. An anti-loosening nut (or two nuts locking each other) 36 (shown only in FIG. 3) tightens onto the floor anchor threaded rod 20 to secure the bracket 30, and more particularly the horizontal mounting plate 32 of the bracket 30, to the floor anchor 20.

The bracket 30 further includes a vertical plate 40 that is connected with the horizontal mounting plate 32 to form a single rigid bracket. For example, the vertical plate 40 and the horizontal mounting plate 32 may be manufactured as a single forged piece, or may be cast as a single cast piece. Alternatively, the vertical plate 40 and the horizontal mounting plate 32 may be manufactured as separate pieces that are welded together. The vertical plate 40 has one or more (illustrative two) through-slots 42 oriented in a vertical direction (indicated by a double-arrow labeled V in the drawings) when the bracket 30 is secured to the floor anchor 20. The magnet mounting 22 has matching through-hole(s) 44 (see FIG. 6) that align with respective through-slots 42 of the bracket 30, so that fastener(s) can secure the magnet mounting 22 to the vertical plate 40 of the bracket. In the illustrative example, each fastener includes a bolt 46 (see FIGS. 3 and 6) that passes through the through-slot 42 and through-hole 44 and is secured at its opposite end by a nut 48 (see FIG. 6). The through-slots 42 enable the height of the bracket 30 in the vertical direction V to be adjusted. For example, FIG. 2 illustrates the magnet is at a level L at which the bolts 46 are located. The left bracket shown in FIG. 2 is positioned at the lowest achievable bracket height z_{L} by having the bolts 46 at the tops of the through-slots 42; whereas, the right bracket shown in FIG. 2 is positioned at the highest achievable bracket height z_{H} by having the bolts 46 at the bottoms of the through-slots 42. Such height adjustment capability enables the brackets 30 to accommodate the possibility that the structural floor 16 is not perfectly level.

The bracket 30 further includes a flat bracket-side locking surface 50 which is vertically oriented and disposed on the vertical plate 40, and has surface features that are periodic with a pitch P in the vertical direction (see “Detail B” of FIG. 5). The illustrative surface features of the locking surface 50 are mutually parallel horizontal grooves and/or ridges (alternatively may be referred to as “teeth”) spaced apart in the vertical direction V by a constant spacing (or pitch) P. in the illustrative example of FIGS. 4-6. For manufacturing convenience, the bracket-side locking surface 50 is disposed on a separate bracket-side locking plate 52 which fits into a recess or pocket 54 (see FIG. 6) of the vertical plate 40 of the bracket 30 to prevent the locking plate 52 from moving. The locking plate 52 may be held in the recess or pocket 52 by adhesive or by fasteners. Clearance between the perimeter of the locking plate 52 and the perimeter of the recess 54 should be tight to prevent movement of locking plate 52 disposed in the recess 54. The bracket-side locking plate 52 includes vertical through-slots 56 matching the vertical through-slots 42 of the vertical plate 40 of the bracket 30 so that the bracket-side locking plate 52 does not impede the bolt(s) 46. Alternatively, the locking surface 50 could be formed integrally into the bracket 30, i.e. integrally into the vertical plate, e.g. by machining the horizontal ridges and/or grooves (i.e. teeth) into the blank plate surface.

Furthermore, a flat component-side locking surface 60 is integral with or secured with the component that is mounted by the bracket 30. In the instant case that component is the MR magnet 10, and hence the component-side locking surface 60 may be deemed a magnet-side locking surface 60. The magnet-side locking surface 60 includes mutually parallel grooves or ridges having the (same) pitch P in the vertical direction V as the grooves or ridges of the bracket-side locking surface 50. Again for manufacturing convenience, the component-side locking surface 60 is formed in a component-side locking plate 62 having opposite first and second sides. The first side is secured to the magnet mounting 22, for example using structural adhesive, fasteners, or the like; while, the second side is the component-side locking surface 60. Alternatively, the component-side locking surface 60 may be formed directly into the surface of the magnet mounting 22, e.g. by machining the grooves or ridges. The magnet-side locking plate 62 includes through-holes 64 matching the through-holes 44 of the magnet mounting 22 so that the magnet-side locking plate 62 does not impede the bolt(s) 46.

As best seen in “Detail B” of FIG. 5, the surface features of the bracket-side locking surface 50 and the surface features of the magnet-side locking surface 60 engage or lock together so as provide resistance to vertical movement due to seismic forces. This resistance is additional to the resistance to vertical movement due to seismic forces provided by the pre-load torque and friction of the bolt/nut fastener 46, 48. Advantageously, because the surface features of the two locking surfaces 50, 60 are periodic in the vertical direction with pitch P, they can be locked together at different relative heights in the vertical direction V, with a “resolution” equal to the pitch P. For example, referencing “Detail B” of FIG. 5, it will be appreciated that the bracket 30 including its locking surface 50 could be disengaged from the magnet-side locking surface 60 and moved up (or down) by a vertical distance equal to any integral multiple (1, 2, 3, . . . ) of the pitch P, and then re-engaged with the magnet-side locking surface 60. If the two locking surfaces 50, 60 have sufficient vertical extent, then this allows the bracket 30 to be moved up or down over the entire height of the through-slot(s) 42 and positioned at any height between the lowest achievable bracket height z_{L} and the highest achievable bracket height z_{H} (see FIG. 2), with the positioning limited only by the “resolution” defined by the vertical pitch P. In this regard, it should be noted that only partial overlap of the two locking surfaces 50, 60 is generally sufficient to provide the desired resisting force to counter vertical seismic forces. For example, in some embodiments as few as three engaged teeth (grooves/ridges) is sufficient.

The choice of surface features (i.e. teeth) of the locking surfaces 50, 60 for providing this vertically adjustable lock can be varied, so long as they exhibit periodicity in the vertical direction of the (same) pitch P. For example, the bracket-side locking surface 50 may have ridges that mate with grooves of the magnet-side locking surface 60. Alternatively, the bracket-side locking surface 50 may have grooves that receive ridges of the magnet-side locking surface 60. In one specific illustrative embodiment, the bracket-side locking surface 50 and the magnet-side locking surface 60 have matching tapered (10° included angle) tongues and grooves that prevent vertical slippage when engaged.

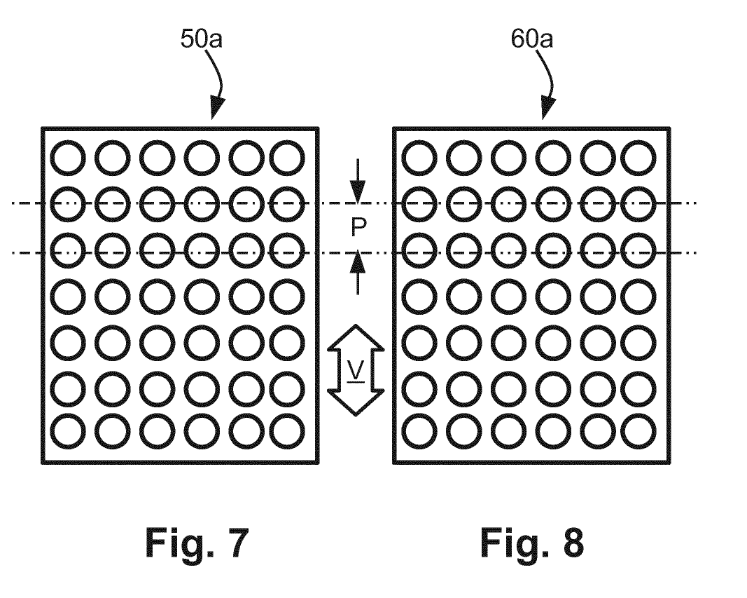

With reference to FIGS. 7 and 8, in another illustrative embodiment a bracket-side locking surface 50a has teeth in the form of bumps (FIG. 7) and a magnet-side locking surface 60a has dimples sized to receive the bumps of the locking surface 50a. This may be reversed, e.g. the magnet-side locking surface may have the bumps and the bracket-side locking surface the dimples. In this embodiment, the locking surfaces 50a, 60a also provide resistance to seismic forces in the horizontal direction (however, the vertical through-slots 42, 56 also resist horizontal movement of the bracket 30 through shear against the attachment bolts 46).

In the disclosed approach, the flat component-side locking surface 60 or 60a is locked with the flat bracket-side locking surface 50 or 50a. These locking surfaces provide additional resistance to vertical seismic forces that enable use of the vertical through-slots 42 to provide adjustable bracket height. Advantageously, in some embodiments no adhesive is disposed between the flat component-side locking surface 60 or 60a and the flat bracket-side locking surface 50 or 50a. Consequently, if the bracket height is to be adjusted, there is no adhesive bond to be broken, and the adjustment merely entails loosening the fastener 46, 48 and moving the bracket vertically to its new height.

The locking surfaces 50, 60 or 50a, 60a provide additional resisting force to counter vertical seismic forces so as to permit vertical bracket adjustment by way of the vertical through-slots 42, 56. Additionally or alternatively, in some embodiments it is advantageous to provide for large horizontal locational tolerance between the bracket 30 and the floor anchor 20.

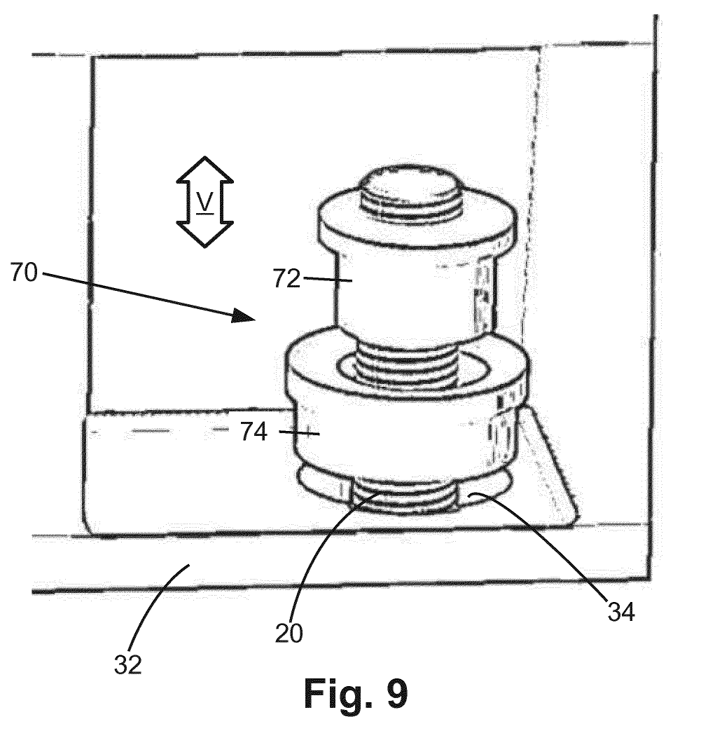

With reference to FIGS. 3-6 and with further reference to FIG. 9, a tolerance zone between the floor anchor 20 and the anchor-mount through-hole 34 of the horizontal mounting plate 32 is provided by an eccentric bushing assembly 70 disposed in the anchor-mount through-hole 34. The eccentric bushing assembly 70 includes an inner eccentric bushing 72 nested in an outer eccentric bushing 74. If electrical isolation is desired, the inner and/or outer eccentric 72 is suitably made of an electrically non-conductive material. If vibrational isolation is desired, this is achieved by the eccentric 72 having an inner diameter larger than the anchor threaded rod 20. Additionally, since vibrations could be transmitted through the junction between the nut 36 and the inner eccentric bushing 72 (see FIG. 3), in some embodiments a gap is provided between the nut 36 and the eccentric bushing assembly 70 (and more particularly between the nut 36 and the inner eccentric bushing 72). The gap should be chosen to be large enough to suppress vibrational coupling between the nut 36 and the inner eccentric bushing 72, but small enough that the vertical movement permitted by the gap (e.g. during a seismic event) is acceptably small. In some embodiments, a gap in a range of 1.0-3.0 mm is employed, with some specific embodiments employing a 1.5 mm gap.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof.

1. A seismic mounting bracket assembly comprising:
a bracket configured to be secured to a floor anchor, the bracket including one or more through-slots oriented in a vertical direction when the bracket is secured to the floor anchor, the bracket further including a flat bracket-side locking surface on a single face of the bracket, the flat bracket side locking surface having surface features that are periodic with a pitch P in the vertical direction; and
a flat component-side locking surface configured to lock to the single face of the bracket including the flat bracket-side locking surface with one or more through-holes of the flat component-side locking surface aligned with the one or more through-slots of the bracket, the flat component-side locking surface having surface features that are periodic with the pitch P oriented in the vertical direction when the flat component-side locking surface is locked with the flat bracket-side locking surface.

2. The seismic mounting bracket assembly of claim 1 wherein:
the surface features of the flat bracket-side locking surface comprise one of mutually parallel horizontal ridges spaced apart by the pitch P and mutually parallel horizontal grooves spaced apart by the pitch P; and
the surface features of the flat component-side locking surface comprise the other of mutually parallel horizontal ridges spaced apart by the pitch P and mutually parallel horizontal grooves spaced apart by the pitch P.

3. The seismic mounting bracket assembly of claim 1 wherein:
the flat component-side locking surface is locked with the flat bracket-side locking surface; and
no adhesive is disposed between the flat component-side locking surface and the flat bracket-side locking surface.

4. The seismic mounting bracket assembly of claim 1 wherein the bracket further comprises:
a horizontal mounting plate having an anchor-mount through-hole sized to receive a floor anchor comprising a threaded rod; and
an eccentric brushing assembly disposed in the anchor-mount-through-hole, the eccentric brushing assembly comprising nested outer and inner eccentric brushings.

5. (canceled)

6. The seismic mounting bracket assembly of claim 1 wherein the bracket includes:
a bracket-side locking plate disposed in a recess of the bracket, the bracket-side locking plate including the flat bracket-side locking surface.

7. The seismic mounting bracket assembly of claim 1 further comprising:
a component-side locking plate including the flat component-side locking surface.

8. (canceled)

9. A superconducting magnet assembly comprising:
a superconducting magnet having a plurality of magnet mountings, each magnet mounting including a flat component-side locking surface; and
a plurality of seismic mounting bracket assemblies as set forth in claim 1 corresponding to the plurality of magnet mountings of the superconducting magnet, wherein the flat component-side locking surface of each magnet mounting is the flat component-side locking surface of the corresponding seismic mounting bracket assembly.

10. The superconducting magnet assembly of claim 9 wherein the mating surface features of the respective locking surfaces of the magnet mounting and the seismic mounting bracket (30) comprise mating horizontal teeth spaced apart on each respective locking surface by the pitch P in the vertical direction.

11. (canceled)

12. The superconducting magnet assembly of claim 9 wherein the seismic mounting bracket further comprises:
a horizontal mounting plate having an anchor-mount through-hole sized to receive a threaded rod floor anchor.

13. The superconducting magnet assembly of claim 12 wherein the seismic mounting bracket further comprises:
an eccentric bushing assembly disposed in the anchor-mount through-hole, the eccentric bushing assembly comprising nested outer and inner eccentric bushings.

14. The superconducting magnet assembly of claim 13 wherein the seismic mounting bracket further comprises:
a nut threaded onto the threaded rod floor anchor with a gap between the nut and the eccentric bushing assembly.

15. The superconducting magnet assembly of claim 9 wherein each magnet mounting comprises:
a locking plate having the locking surface of the magnet mounting.

16. A seismic mounting bracket assembly comprising:
a bracket including a vertical plate having one or more vertical through-slots and a horizontal plate having a through-hole sized to receive a threaded rod floor anchor; and
an eccentric brushing assembly disposed in the anchor-mount-through-hole, the eccentric brushing assembly comprising
a nested outer and inner eccentric bushings disposed in the through-hole of the horizontal plate.

17. The seismic mounting bracket assembly of claim 16 further comprising:
a bracket-side locking surface disposed on the vertical plate and having surface features which are periodic in the vertical direction with a pitch P

18. The seismic mounting bracket assembly of claim 17 further comprising:
a component-side locking plate locked with the bracket-side locking surface by surface features of the component-side locking plate which are periodic in the vertical direction with the pitch P.

19. (canceled)

20. (canceled)

21. (canceled)

22. The seismic mounting bracket assembly of claim 12 further comprising:
a nut threaded onto the threaded rod floor anchor with a gap between the nut and the eccentric bushing assembly.

23. A superconducting magnet assembly comprising:
a superconducting magnet having a plurality of magnet mountings; and
a plurality of seismic mounting bracket assemblies as set forth in claim 12, each corresponding to, and secured by the vertical plate with, one of the plurality of magnet mountings of the superconducting magnet.
